(19) United States
(12) Patent Application Publication
(10) Pub. No.: US 2003/0042591 A1
(43) Pub. Date: Mar. 6, 2003

(54) Electronic component with at least two stacked semiconductor chips, and fabrication method

(76) Inventors: Bernd Goller, Kemnath (DE); Gerald Ofner, Bad Abbach (DE); Josef Thumbs, Breitenbrunn (DE); Holger Worner, Regensburg (DE); Robert-Christian Hagen, Sarching (DE); Christian Stumpfl, Schwandorf (DE); Stefan Wein, Regensburg (DE)

Correspondence Address: LERNER AND GREENBERG, P.A., PATENT ATTORNEYS AND ATTORNEYS AT LAW, Post Office Box 2480, Hollywood, FL, 33020-2480, US

(21) Appl. No.: 10/232,173

(22) Filed: Aug. 30, 2002

(30) Foreign Application Priority Data
Aug. 30, 2001 (DE) 101 42 117.6

(51) Int. Cl. H01L 23/02

(52) U.S. Cl. 257/686

(57) ABSTRACT

An electronic component is formed with at least two semiconductor chips disposed on a carrier substrate. Active chip surfaces of the semiconductor chips comprise central contact surfaces, respectively, on which opposing solder contact surfaces are formed. These are conductively connected to an intermediate carrier which is disposed between the semiconductor chips and which produces rewirings from the chips to the carrier substrate.

### BACKGROUND OF THE INVENTION

1. Field of the Invention

The present invention relates to an electronic component with at least two stacked semiconductor chips and a method for fabricating such an electronic component.

In many electronic components, a first semiconductor chip module, for instance a logic module, and a second semiconductor module, for instance a memory module, are needed. In order to save space on a PCB, it makes sense to house both semiconductor chip modules in a common housing with an optimally low space requirement. A logic module typically has a square surface, and a memory module has a rectangular surface, so that when semiconductor chip modules are stacked as in a known chip-on-chip structure, the bond contact surfaces partly overlap. One solution to this problem is to arrange the two semiconductor chip modules side by side in one housing, which results in a substantial consumption of space. In an alternative solution, the two semiconductor chip modules are mounted in a lead frame housing, which is associated with a complex and difficult assembly, because the components must be turned several times with bond wires partly exposed. Another principle is also applied, according to which the semiconductor chip modules are mounted in different housings, which are then stacked. But this is a cost-intensive method, and furthermore, it leads to large mounting heights of the electronic component.

The Japanese disclosure document JP 08250651-A describes a semiconductor configuration in which two semiconductor chip modules are stacked in spaces which are separated by a dividing wall. The two semiconductor chip modules are connected with the aid of bond wires to external contacts by way of interconnects. That prior art semiconductor configuration takes up a relatively large component volume and it is complicated and expensive to fabricate.

### SUMMARY OF THE INVENTION

It is accordingly an object of the invention to provide an electronic component and a fabrication method, which overcome the above-mentioned disadvantages of the heretofore-known devices and methods of this general type and wherein the component is easy to build and inexpensive to fabricate, and wherein the component takes up a minimum of space.

With the foregoing and other objects in view there is provided, in accordance with the invention, an electronic component, comprising:

a first semiconductor chip having an active chip surface with a central contact surface formed with individual solder contact surfaces;

a second semiconductor chip having an active chip surface with a central contact surface formed with individual solder contact surfaces;

a carrier substrate supporting said first and second semiconductor chips with said central contact surfaces of said first and second semiconductor chips facing one another; and

an intermediate carrier disposed between said first and second semiconductor chips, with said individual solder contact surfaces on said central contact surfaces of said semiconductor chips opposing one another and being electrically connected to said intermediate carrier, and said intermediate carrier forming rewirings from said semiconductor chips to said carrier substrate.

In other words, an electronic component according to the invention comprises at least one first semiconductor chip and at least one second semiconductor chip as well as a carrier substrate for receiving the semiconductor chips. Active chip surfaces of the first and second semiconductor chips each comprise a central contact surface. The two central contact surfaces of the first and second semiconductor chips are arranged facing one another so that individual solder contact surfaces which are realized on the central contact surfaces of the two semiconductor chips are situated opposite one another. The solder contact surfaces are conductively connected to an intermediate carrier that is arranged between the semiconductor chips and that produces rewirings from the semiconductor chips to the carrier substrate.

The inventive electronic component has the advantage that two chips with different outer dimensions can be housed in a common housing in an extremely space-efficient fashion owing to the central contact surfaces, which face one another, of two semiconductor chips, with their correspondingly allocated solder contact surfaces. It is thus possible to stack a square semiconductor chip with a rectangular semiconductor chip and vice versa, whereby the semiconductor chips only partly overlap, and whereby both semiconductor chips include regions protruding beyond the overlap, respectively. No feasible solution can be found in the prior art for such different outer dimensions.

An embodiment of the invention provides that the intermediate carrier reaches at least partway around the first semiconductor chip and is conductively connected on at least two opposite sides to a top side of the carrier substrate. In this embodiment, the intermediate carrier has a U-shaped contour in cross-section, with the two legs of the U sitting on the carrier substrate. This embodiment makes possible highly compact housing designs for the electronic component.

Another embodiment of the invention provides that a first side of the intermediate carrier is conductively connected to the first central contact surface of the first semiconductor chip, and that a second side of the intermediate carrier is conductively connected to the second central contact surface of the second semiconductor chip. The unique advantage of this embodiment is that the intermediate carrier allows a rewiring between semiconductor chips with different sizes that are stacked on top of one another. A semiconductor chip is disposed on each side of the intermediate carrier and conductively connected to the intermediate carrier. This way, the first semiconductor chip can be substantially larger than the second semiconductor chip.

According to another embodiment of the invention, contact bumps are respectively provided between first terminal contacts on the first side of the intermediate carrier and the first solder contact surfaces of the first central contact surface, and between second terminal contacts on the second side of the intermediate carrier and the second solder contact surfaces of the second central contact surface. The advantage of this embodiment is that the two semiconductor chips can be effectively and economically contacted with the intermediate carrier by a single heating process. The contact bumps can be conductively connected to the solder contact surfaces of the first and second semiconductor chips by eutectic soldering, for example. The contact bumps can be constructed as column bumps whose height is greater than the radius of their base surface. Such a configuration of the contact bumps makes possible a precise and efficient contacting between the two semiconductor chip modules and the intermediate carrier, whereby the conductive connection between the two semiconductor chips is advantageously achieved by flip chip technology.

According to an embodiment of the invention, the ends of the interconnects of the rewirings of the intermediate carrier are conductively connected to contact surfaces of the carrier substrate, which has the advantage of a highly compact rewiring of the two semiconductor chips. The carrier substrate can be provided with additional contact bumps for flip chip assembly on its bottom side which is averted from the semiconductor chips, the advantage being that the electrical connection can be produced rapidly and easily. The carrier substrate is advantageously constructed as a rewiring board, whereby a rewiring is formed from the ends of interconnects of the intermediate carrier to the additional contact bumps of the carrier substrate.

The first semiconductor chip can have a square shape and can be a memory module. The second semiconductor chip can have a rectangular shape and can be a logic module. Additional bond wires can potentially be provided for conductively connecting the first semiconductor chip to the carrier substrate.

An alternative embodiment of the invention provides that an arrangement of the first and second semiconductor chips connected to one another by way of an intermediate carrier is disposed on a first chip island on the top side of the carrier substrate and on a second chip island on the opposite bottom side of the carrier substrate. This embodiment of the invention has an extremely compact structure owing to the fact that the carrier substrate is provided with semiconductor chips on both sides.

An inventive method for fabricating an electronic component with at least one first semiconductor chip and at least one second semiconductor chip and a carrier substrate for receiving the semiconductor chips according to one of the foregoing embodiments has the following steps: After a first semiconductor chip with a first central contact surface on a first active chip surface is supplied, a second semiconductor chip with a second central contact surface on a second active chip surface is supplied. Next, a carrier substrate with at least one chip island and contact surfaces is supplied. The first semiconductor chip is then fastened on the chip island of the carrier substrate by means of a conductive adhesive layer or a solder layer, whereupon a first side of an intermediate carrier is placed over the first semiconductor chip. Next, first terminal contacts of the intermediate carrier are connected to the first solder surfaces of the first semiconductor chips by flip chip technology. The second semiconductor chip is then placed on a second side of the intermediate carrier. This is followed by the connecting of second terminal contacts of the intermediate carrier to the second solder contact surfaces of the second semiconductor chip by flip chip technology. Lastly, the electronic component is cast in a housing.

The advantage of this method for fabricating an electronic component is its very short fabrication times, it being possible to perform the electrical contacting between the first and second semiconductor chips and the intermediate carrier in a time-saving fashion by means of the central contact surfaces of the two opposing semiconductor chips, owing to the application of flip chip technology. Moreover, the product of the method, the electronic component, is highly compact. According to an exemplifying embodiment of the invention, a first semiconductor chip and a second semiconductor chip are disposed on the chip island of the top side of the substrate and on the opposite chip island of the bottom side of the substrate, with the advantage that the power of such electronic components is additionally increased, while the space consumption is appreciably reduced.

In summary, in electronic components a first semiconductor chip, for instance a logic module, and a second semiconductor chip, for instance a memory module, are needed. In order to save space on a PCB, it makes sense to house both semiconductor chips in a common housing with an optimally low space requirement. The invention makes available an electronic component in which all electrical terminals of the two semiconductor chips are arranged as solder contact pads in a central contact surface, so that the semiconductor chips can be fastened to an intermediate carrier by flip chip technology. Their contact pads are situated opposite one another on either side of the intermediate carrier. The electrical contacting is achieved by means of contact bumps which are constructed as column bumps and which conductively connect the contact surfaces of the stacked semiconductor chips to the intermediate carrier as high-melting solder joints. The intermediate carrier is sometimes referred to as a chip interposer and can consist of a flexible or rigid material. If a polyimide film or tape is used, which can be glass reinforced, the large differences in the coefficients of expansion of the silicon and the carrier substrate do not adversely affect the electrical connections between the semiconductor chips and the intermediate carrier.

Other features which are considered as characteristic for the invention are set forth in the appended claims.

Although the invention is illustrated and described herein as embodied in an electronic component with at least two stacked semiconductor chips and fabrication method, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic plan view of a first semiconductor chip;

FIG. 2 is a schematic plan view of a second semiconductor chip; and

FIG. 3 is a schematic cross-sectional view of a novel electronic component according to the invention.

### DESCRIPTION OF THE PREFERRED EMBODIMENTS

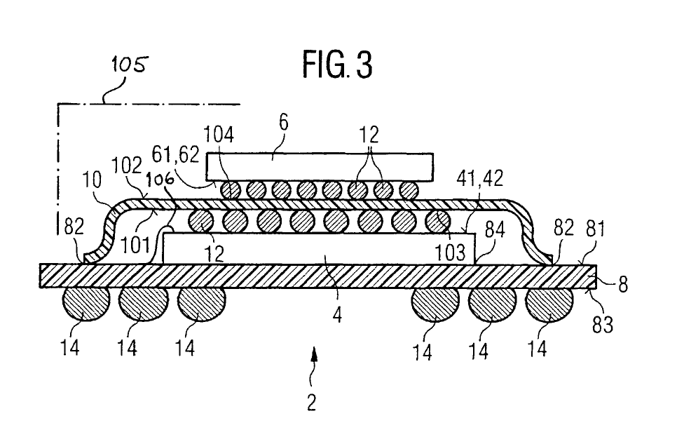

Referring now to the figures of the drawing in detail and first, particularly, to FIG. 1 thereof, there is shown a schematic representation of a first semiconductor chip 4 in a top view of a first active chip surface 41. There are provided a plurality of first solder contact surfaces 43 on the first chip surface 41, which together form a first central contact surface 42. The first central contact surface 42 is slightly or substantially smaller than the first active chip surface 41. The semiconductor chip 4 has a square shape and it may be, by way of example, a logic module. Contact bumps, for instance solder balls, are installed on the first solder contact surfaces 43, as represented in FIG. 3.

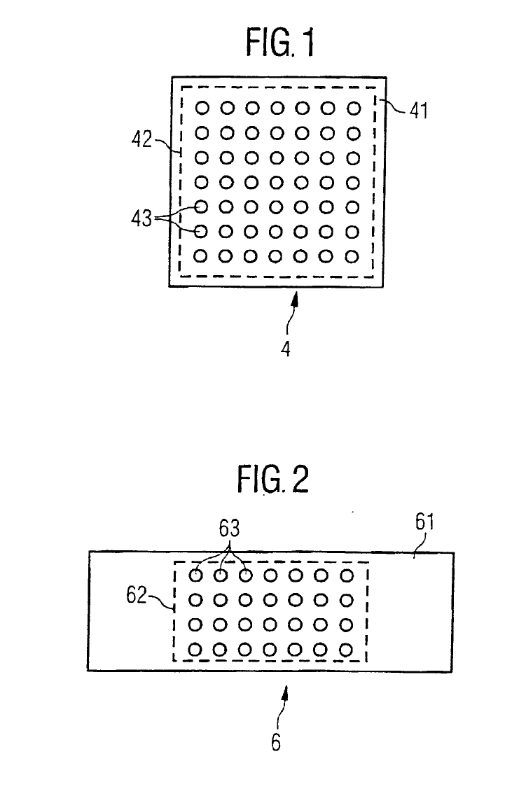

With reference to FIG. 2, there is illustrated a schematic representation of a second semiconductor chip 6 in a top view of a second active chip surface 61. There are likewise a plurality of second solder contact surfaces 63 on this second active chip surface, which together form a second central contact surface 62. In the exemplary embodiment, the second solder contact surface 63 is smaller than the second active chip surface 61. The second semiconductor chip 6 has a rectangular geometric shape and can be a memory module, for example.

FIG. 3 is a schematic cross-sectional view of an inventive electronic component 2. A first semiconductor chip 4 and an intermediate carrier 10 are fastened to a top side 81 of a flat carrier substrate 8. The passive back side of the first semiconductor chip 4 is fastened on a first chip island 84 of the top side 81 of the carrier substrate 8, for instance with the aid of a conductive adhesive layer or solder layer. The first solder contact pads 43 on the first central contact surface 42 of the first active chip surface 41 are provided with contact bumps 12, which produce a conductive connection to first terminal contacts on the first side of the intermediate carrier 10 by means of soldering. The opposite second side 102 of the chip carrier 10 is provided with second terminal contacts 104, which make contact with contact bumps 12 of a second semiconductor chip 6. The contact bumps 12 of the second semiconductor chip 6 are located on second solder contact pads 63 in the second central contact surface 62 of the second active chip surface 61 and produce an electrical connection to the second terminal contacts 104 by means of soldering.

The intermediate carrier 10 functions as a rewiring of the electrical contacts of the first and second semiconductor chips 4, 6 and is provided with conductive tracks on both sides 101, 102, whose ends terminate at contact surfaces 82 of the top side 81 of the carrier substrate 8 and are conductively connected to this substrate.

The bottom side 83 of the carrier substrate 8 is provided with additional contact bumps 14, by way of which a conductive connection to a PCB or the like can be produced.

The carrier substrate 8 can consist of ceramic or an epoxy material such as is used for PCBs. The intermediate carrier 10 can consist of a polyimide film or layer or alternatively an epoxy material. Glass fibers can be embedded therein for reinforcement.

In an inventive method for fabricating the electronic component 2, a passive back side of a first semiconductor chip 4 is connected to a chip island 84 on a top side 81 of a flat carrier substrate 8, for instance by soldering or gluing. The first active chip surface 41 of the semiconductor chip 4, which is opposite the passive back side, is provided with a first central contact surface 42 on whose first solder contact surfaces 43 contact bumps 12 are respectively located.

After the first semiconductor chip 4 is installed, a flat bent intermediate carrier 10 is placed on the carrier substrate 8, so that the first side 101 of the intermediate carrier 10 with the first terminal pads 103 is located over the first chip surface 41 of the first semiconductor chip 4.

The first terminal pads 103 are placed on the corresponding contact bumps 12 and connected by flip chip technology.

The intermediate carrier 10 surrounds the first semiconductor chip 4 laterally, with its side legs, and the conductive tracks that terminate there, situated on contact surfaces 82 of the carrier substrate and preferably soldered thereto.

A second semiconductor chip 6 is then placed on the second side 102 of the intermediate carrier 10 and connected to it by flip chip technology. To that end, contact bumps 12 are located on second solder contact surfaces 63 within a second central contact surface 62 on the second active chip surface 61, which bumps are placed on corresponding second terminal pads 104 on the second side 102 of the intermediate carrier 10 and melted into solder joints.

It is further possible to provide a number of bond wires 106 to conductively connect the first semiconductor chip 4 to the carrier substrate 8. The bond wires 106 may share in connecting the chip 4 with the connections via the intermediate carrier.

Lastly, the electronic component 2 is provided with a housing. The housing is schematically illustrated with a partial dash-dotted outline and identified with numeral 105.

We claim:

1. An electronic component, comprising:
a first semiconductor chip having an active chip surface with a central contact surface formed with individual solder contact surfaces;
a second semiconductor chip having an active chip surface with a central contact surface formed with individual solder contact surfaces;
a carrier substrate supporting said first and second semiconductor chips with said central contact surfaces of said first and second semiconductor chips facing one another; and
an intermediate carrier disposed between said first and second semiconductor chips, with said individual solder contact surfaces on said central contact surfaces of said semiconductor chips opposing one another and being electrically connected to said intermediate carrier, and said intermediate carrier forming rewirings from said semiconductor chips to said carrier substrate.

2. The electronic component according to claim 1, wherein said intermediate carrier at least partly surrounds said first semiconductor chip and said intermediate carrier is conductively connected to a top side of said carrier substrate on at least two opposing sides.

3. The electronic component according to claim 1, wherein a first side of said intermediate carrier is conductively connected to said central contact surface of said first semiconductor chip, and a second side of said intermediate carrier is conductively connected to said central contact surface of said second semiconductor chip.

4. The electronic component according to claim 3, which comprises contact bumps respectively disposed between first terminal pads on said first side of said intermediate carrier and said solder contact surfaces on said central contact surface of said first semiconductor chip, and between second terminal pads on said second side of said intermediate carrier and said solder contact surfaces on said central contact surface of said second semiconductor chip.

5. The electronic component according to claim 4, wherein said contact bumps are conductively connected to said solder contact surfaces and said terminal pads by eutectic soldering.

6. The electronic component according to claim 1, wherein said carrier substrate is formed with contact surfaces and said rewirings of said intermediate carrier has interconnects formed with ends conductively connected to said contact surfaces.

7. The electronic component according to claim 1, wherein said first semiconductor chip and said second semiconductor chip are conductively connected to said intermediate carrier by a flip-chip technology process.

8. The electronic component according to claim 1, wherein said carrier substrate is formed with additional contact bumps for flip chip assembly on a bottom side distal from said semiconductor chips.

9. The electronic component according to claim 1, wherein said carrier substrate is a rewiring board.

10. The electronic component according to claim 1, wherein said first semiconductor chip is a memory module having a square shape.

11. The electronic component according to claim 1, wherein said second semiconductor chip is a logic module having a non-square, rectangular shape.

12. The electronic component according to claim 1, which further comprises an intermediate housing enclosing said first semiconductor chip, said second semiconductor chip, and said intermediate carrier.

13. The electronic component according to claim 1, wherein additional bond wires are provided for conductively connecting the first semiconductor chip to the carrier substrate.

14. The electronic component according to claim 1, wherein said carrier substrate is formed with a first chip island on a top side thereof and with a second chip island on an opposite, bottom side thereof, and wherein a first assembly of a respective said first semiconductor chip, said second semiconductor chip, and said intermediate carrier therebetween is disposed on said first chip island, and wherein a second assembly of a respective said first semiconductor chip, said second semiconductor chip, and said intermediate carrier therebetween is disposed on said second chip island of said carrier substrate.

15. A method of fabricating an electronic component, the method which comprises the following steps:
providing a first semiconductor chip with a first central contact surface on a first active chip surface;
providing a second semiconductor chip with a second central contact surface on a second active chip surface;
providing a carrier substrate with at least one chip island and contact surfaces;
fastening the first semiconductor chip on the chip island of the carrier substrate with a conductive adhesive layer or a solder layer;
placing a first side of an intermediate carrier over the first semiconductor chip;
connecting first terminal pads of the intermediate carrier to the first solder contact surfaces of the first semiconductor chip by flip chip technology;
placing the second semiconductor chip on a second side of the intermediate carrier;
connecting second terminal pads of the intermediate carrier to the second solder contact surfaces of the second semiconductor chip by flip chip technology; and
casting the electronic component in a housing.

16. The method according to claim 15, which comprises conductively connecting the intermediate carrier to the top side of the carrier substrate.

17. The method according to claim 15, which comprises conductively connecting the ends of interconnects of the intermediate carrier to contact surfaces on the top side of the carrier substrate.

18. The method according to claim 15, which comprises attaching a first assembly formed with a first and a second semiconductor chip on the first chip island of the top side of the carrier substrate and, attaching on the opposite, second chip island of the bottom side of the carrier substrate a second assembly of a first and a second semiconductor chip.

19. The method according to claim 15, which comprises fabricating an electronic component with at least one first semiconductor chip, at least one second semiconductor chip, and a carrier substrate for receiving the semiconductor chips, wherein active chip surfaces of the first and second semiconductor chips comprise respective central contact surfaces which face each other, and wherein individual solder contact surfaces on the central contact surfaces of the two semiconductor chips oppose each other and are conductively connected to an intermediate carrier arranged between the semiconductor chips and which produces rewirings from the semiconductor chips to the carrier substrate.
